(19) United States
(12) Patent Application Publication
(10) Pub. No.: US 2008/0124634 A1
(43) Pub. Date: May 29, 2008

(54) METHOD OF MANUFACTURING LIQUID CRYSTAL DISPLAY

(75) Inventor: Jung-yong LEE, Seongnam-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 11/774,010

(22) Filed: Jul. 6, 2007

(30) Foreign Application Priority Data
Nov. 29, 2006 (KR) 2006-119128

(51) Int. Cl. G03F 1/00

(52) U.S. Cl. 430/7

(57) ABSTRACT

A method of manufacturing a liquid crystal display (LCD). The method includes: forming a plurality of color filters by line-printing a plurality of color inks on a transparent substrate in a longitudinal direction of the color filter array; diving the plurality of color filters so that the color filters can correspond to pixel regions; and forming black matrices between the divided color filters.

### CROSS-REFERENCE TO RELATED APPLICATIONS

This application claims the benefit of Korean Patent Application No. 10-2006-0119128, filed on Nov. 29, 2006, in the Korean Intellectual Property Office, the disclosure of which is incorporated herein in its entirety by reference.

### BACKGROUND OF THE INVENTION

1. Field of the Invention

The present general inventive concept relates to a method of manufacturing a color filter array of a liquid crystal display (LCD).

2. Description of the Related Art

Cathode ray tube (CRT) monitors have been generally used as television (TV) or computer monitors to display information. However, as screens become larger, flat panel displays, such as liquid crystal displays (LCDs), plasma display panels (PDPs), organic electroluminescent (EL) displays, light emitting diodes (LEDs), or field emission displays (FEDs), have been developed and used in recent years. Among the flat panel displays, LCDs have the advantage of low power consumption and thus are preferred for use in computer monitors, notebooks, personal computers (PCs), and so on.

In general, LCDs include a color filter array that transmits selected wavelengths of white light modulated by a liquid crystal layer and forms a desired color image. Color filter arrays are constructed such that a plurality of red (R), green (G), and blue (B) pixels are arranged in a predetermined configuration on a transparent substrate and are divided by black matrices.

FIGS. 1A through 1C are cross-sectional views illustrating a conventional method of manufacturing a color filter array. FIG. 2 is a perspective view illustrating another conventional method of manufacturing a color filter array.

In FIGS. 1A through 1C, black matrices 11 are formed on a transparent substrate 10, and red ink 20 is applied onto the black matrices 11 and is filled in pixels defined by the black matrices 11. Next, a photomask 30 is placed on the resultant structure, exposed to ultraviolet rays, patterned, and developed, and then the red ink on portions others than desired portions are removed. The process is repeated to fill desired pixels with green (G) ink and blue (B) ink also.

However, the conventional method of FIGS. 1A through 1C has a problem in that the number of processes increases because the process of FIGS. 1 through 1C must be repeated.

Referring to FIG. 2, while an inkjet head 50 having a plurality of nozzles formed therein is moved above a transparent substrate 40 on which black matrices 41 are formed, desired ink, for example, a plurality of red ink droplets, are ejected onto the transparent substrate 40 to fill pixels 42, thereby completing a color filter array.

The conventional method of manufacturing the color filter array of FIG. 2 can reduce the number of processes when compared with the conventional method of manufacturing the color filter array of FIG. 1. However, the method of manufacturing the color filter array of FIG. 2 has a problem in that it is difficult to eject a desired amount of ink into a pixel, which is important, due to a surface tension between the ink and the transparent substrate 40 and between the ink and the black matrices 41, thereby failing to achieve desired ink morphology (uniformity).

### SUMMARY OF THE INVENTION

The present general inventive concept provides a method of manufacturing a color filter array of a liquid crystal display (LCD), which can reduce the number of processes and allow ink to be filled in a desired shape into a pixel.

Additional aspects and utilities of the present general inventive concept will be set forth in part in the description which follows and, in part, will be obvious from the description, or may be learned by practice of the general inventive concept.

The foregoing and/or other aspects and utilities of the general inventive concept may be achieved by providing a method of manufacturing a color filter array, the method including: forming a plurality of color filters by line-printing a plurality of color inks on a transparent substrate in a longitudinal direction of the color filter array; diving the plurality of color filters so that the color filters can correspond to pixel regions; and forming black matrices between the divided color filters.

The foregoing and/or other aspects and utilities of the general inventive concept may also be achieved by providing a method of manufacturing a color filter array, the method including forming color filters on a transparent substrate, and forming black matrices between the color filters.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIGS. 1A through 1C are cross-sectional views illustrating a conventional method of manufacturing a color filter array;

FIG. 2 is a perspective view illustrating another conventional method of manufacturing a color filter array;

FIGS. 3A through 3K are cross-sectional views illustrating a method of manufacturing a color filter array of a liquid crystal display (LCD) according to an embodiment of the present general inventive concept;

FIG. 4 is a plan view illustrating color filters line-printed on a transparent substrate according to an embodiment of the present general inventive concept;

FIG. 5 is a cross-sectional view illustrating a method of forming a space for a black matrix between adjacent color filters according to an embodiment of the present general inventive concept; and

FIG. 6 is a plan view of a completed color filter array according to an embodiment of the present general inventive concept.

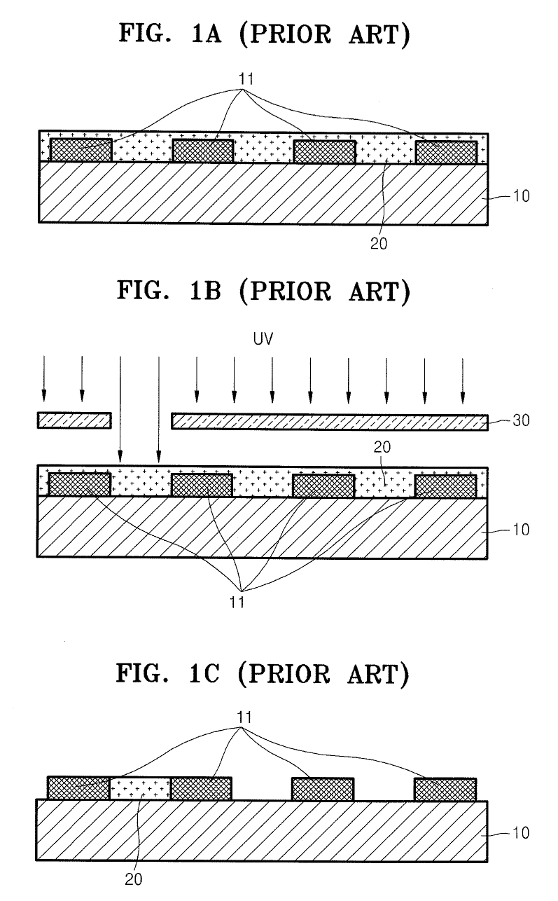

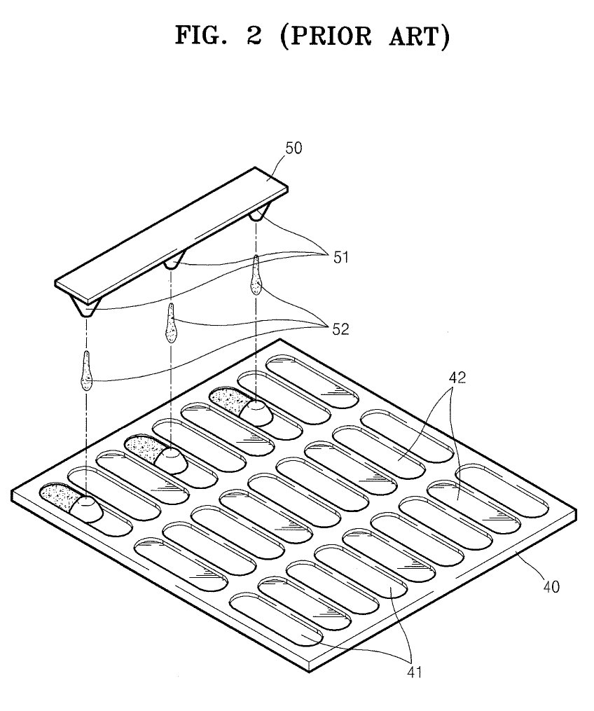

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

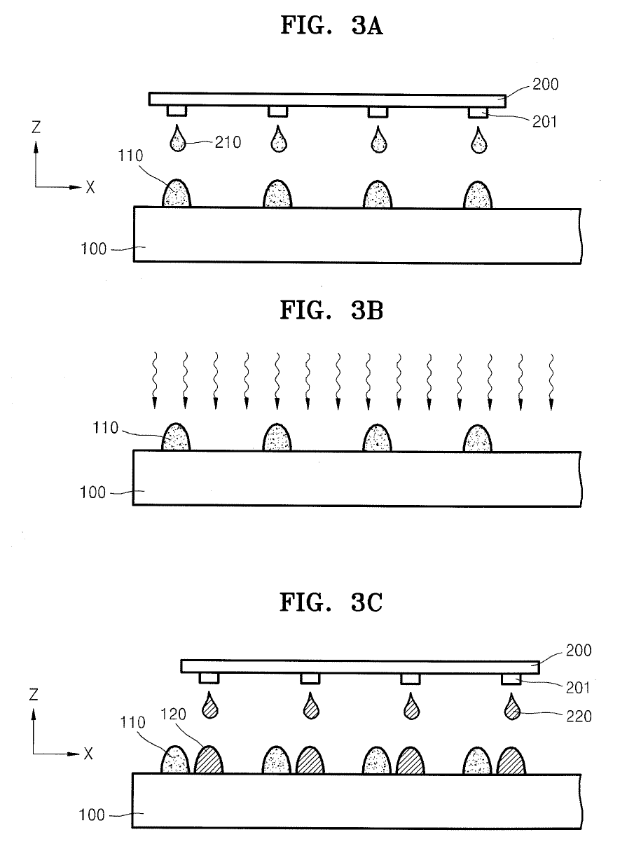

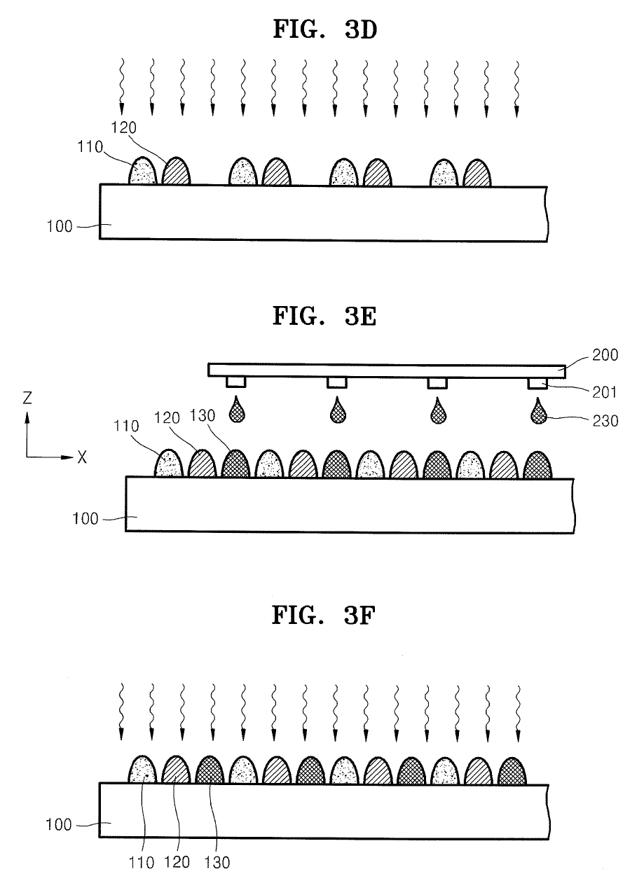

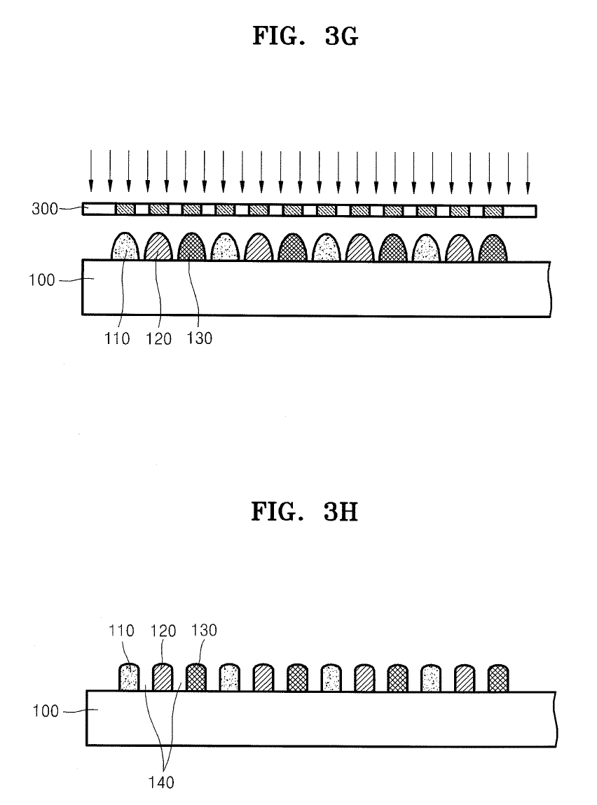

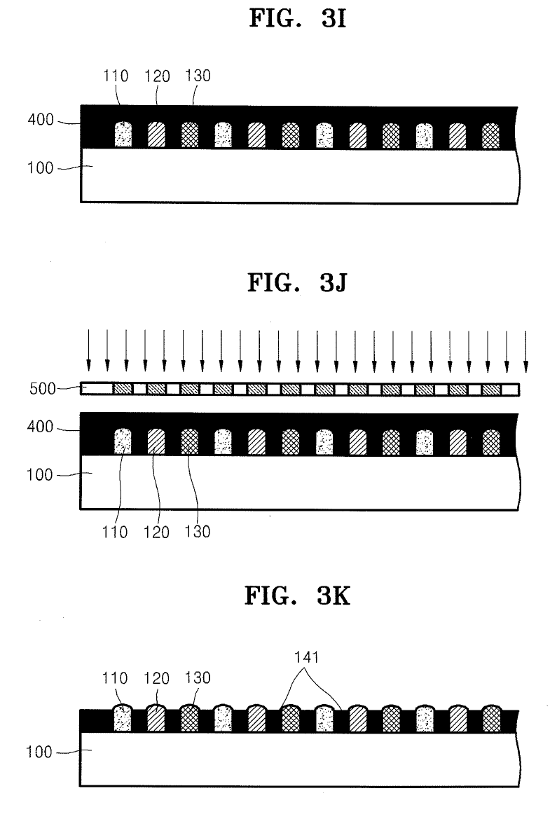

FIGS. 3A through 3K are cross-sectional views illustrating a method of manufacturing a color filter array of a liquid crystal display (LCD) according to an embodiment of the present general inventive concept.

Referring to FIG. 3A, red (R) ink droplets 210 of red (R) ink are ejected from a plurality of nozzles 201, which are arranged at predetermined intervals in an inkjet head 200, onto a transparent substrate 100 to form red (R) color filters 110.

Since the transparent substrate 100 is surface-treated and the red (R) ink has a surface tension of 30 mN/m, the red (R) color filters 110 attached onto the transparent substrate 100 have dome-shaped cross-sections as illustrated in FIG. 3A.

Referring to FIG. 3B, the red (R) color filters 110 attached onto the transparent substrate 100 are heated and dried by baking, to be more stably attached onto the transparent substrate 100.

The red (R) color filters 110 are formed on the transparent substrate 100 by a process of FIGS. 3A and 3B. Since a color filter array includes red (R), green (G), and blue (B) color filters, green (G) color filters and blue (B) color filters need to be formed near the red (R) color filters 110. To this end, ink color is changed and then the process of FIGS. 3A and 3B is repeated. That is, in order to form green (G) color filters, a process of FIGS. 3C and 3D is performed, and in order to form blue (B) color filters, a process of FIGS. 3E and 3F is performed.

Referring to FIG. 3C, the inkjet head 200 having the plurality of nozzles 201 formed therein are moved in an X direction, and green (G) ink droplets 220 are ejected onto a position of the transparent substrate 100 near the plurality of red (R) color filters 110, thereby forming green (G) color filters 120.

Referring to FIG. 3D, the green (G) color filters 120 attached onto the transparent substrate 100 are heated and dried by baking, to be more stably attached onto the transparent substrate 100.

Referring to FIG. 3E, the inkjet head 200 having the plurality of nozzles 201 formed therein is moved in the X direction, and then blue (B) ink droplets 230 are ejected onto a position of the transparent substrate 100 near the plurality of green (G) color filters 120, thereby forming blue (B) color filters 130.

Referring to FIG. 3F, the blue (B) color filters 130 attached onto the transparent substrate 100 are heated and dried by baking, to be more stably attached onto the transparent substrate 100.

Meantime, the red (R) color filters 110, the green (G) color filters 120, and the blue (B) color filters 130 may be attached onto the transparent substrate 100 by line-printing red (R) ink droplets 210, green (G) ink droplets 220, and blue (B) ink droplets 230 on the transparent substrate 100, and baking the same once. That is, the red (R), green (G), and blue (B) color filters 110, 120, and 130 are repeatedly formed on the transparent substrate 100 by the processes of FIGS. 3A, 3C, 3E, and 3F.

FIG. 4 is a plan view illustrating the red (R), green (G), and blue (B) color filters 110, 120, and 130 line-printed and thus repeatedly formed on the transparent substrate 100 by the processes of FIGS. 3A, 3C, 3E, and 3F, according to an embodiment of the present general inventive concept.

The inkjet head 200 in the state of each of FIGS. 3A, 3C, and 3E is moved in a Y direction of the transparent substrate 100 to line-print red (R) color filters 110, green (G) color filters 120, and blue (B) color filters 130 on the transparent substrate 100.

Referring to FIG. 3G a photomask 300 patterned to define positions of black matrices is placed over the transparent substrate 100 on which the red (R) color filters 110, the green (G) color filters 120, and the blue (B) color filters 130 are formed, and then is exposed to light. While a positive photomask, whose exposed portions are removed, is used in FIG. 3G, either a positive photomask or a negative photomask may be selected depending on whether ink is a positive material or a negative material.

Top surfaces of the red (R) color filters 110, the green (G) color filters 120, and the blue (B) color filters line-printed on the transparent substrate 100 may be dome-shaped or flat, and therefore side surfaces are unnecessary and thus need to be removed. Since each of black matrices should be formed between adjacent color filters, the color filters are patterned by the photomask 300 to form spaces for the black matrices.

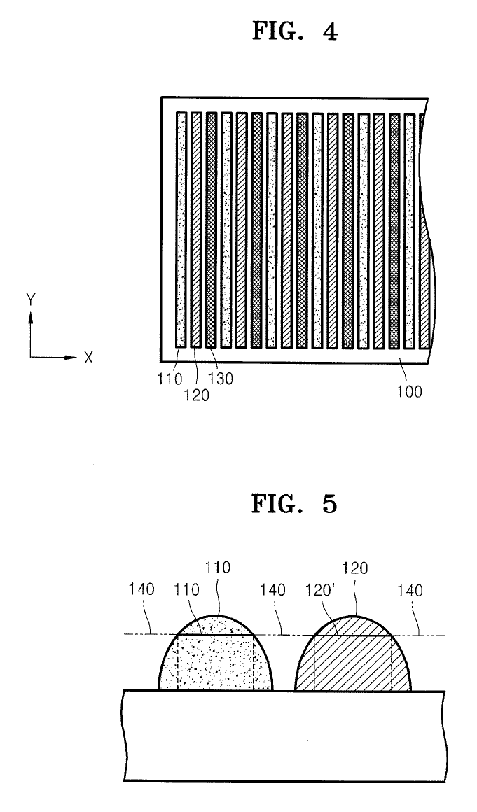

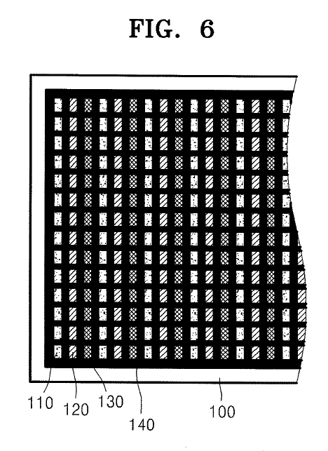

FIG. 5 is a cross-sectional view illustrating a method of forming a space for a black matrix between adjacent color filters according to an embodiment of the present general inventive concept. Referring to FIG. 5, a red (R) color filter 110 and a green (G) color filter 120 are patterned by the photomask 300 of FIG. 3G to form a space 140 for a black matrix between the red (R) color filter 110 and the green (G) color filter 120. That is, unnecessary edges of each color filter are removed to form the space 140 for the black matrix.

Referring to FIG. 3H, the red (R) color filters 110, the green (G) color filters 120, and the blue (B) color filters 130 patterned by the photomask 300 are developed to form spaces 140 for black matrices.

Referring to FIG. 3I, a black matrix layer 400 is coated to a predetermined thickness on the transparent substrate 100 on which the spaces 140 are formed between the color filters 110, 120, and 130.

Referring to FIG. 3J, the black matrix layer 400 is patterned by a negative photomask 500 and then exposed to light.

Referring to FIGS. 3K and 6, the exposed black matrix layer 400 is developed to form black matrices 141. FIG. 6 is a plan view illustrating a completed color filter array according to an embodiment of the present general inventive concept.

As described above, since the plurality of color filters are formed prior to the black matrices, the method of manufacturing the color filter array of the LCD according to the various embodiments can easily be controlled to have uniform ink in the pixels, expand choice of ink in the color filter array, and prevent light leakage due to non-uniform thickness of the color filters.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of manufacturing a color filter array, the method comprising:
forming a plurality of color filters by line-printing a plurality of color inks on a transparent substrate in a longitudinal direction of the color filter array;
dividing the plurality of color filters so that the color filters correspond to pixel regions; and
forming black matrices between the divided color filters.

2. The method of claim 1, wherein the forming of the plurality of color filters comprises line-printing each of the plurality of color inks and baking the color ink, and then repeating the line-printing and baking process.

3. The method of claim 1, wherein the forming of the plurality of color filters comprises line-printing the plurality of color inks and baking the same once.

4. The method of claim 1, wherein the dividing of the plurality of color filters comprises:
removing both edges of each of the plurality of color filters to form predetermined top surfaces of the color filters; and
cutting the color filters in the longitudinal direction of the color filters so that the color filters can correspond to the pixel regions.

5. The method of claim 4, wherein the dividing of the plurality of color filters is performed by photolithography.

6. The method of claim 4, wherein the predetermined top surfaces of the color filters are dome-shaped or flat.

7. The method of claim 1, wherein the forming of the black matrices is performed by photolithography.

8. The method of claim 1, wherein the transparent substrate is surface-treated and the color inks have a surface tension of 30 mN/m.

9. A method of manufacturing a color filter array, the method comprising:
forming color filters on a transparent substrate; and
forming black matrices between the color filters.

10. The method of claim 9, wherein the forming of color filters comprises: sequentially ejecting different colors of ink onto a transparent substrate adjacent to a previous color ink ejected; and
baking the ejected different colors of ink onto the transparent substrate.

11. The method of claim 9, wherein the forming of the black matrices between the color filters comprises:
patterning the color filters on the transparent substrate using a photomask;
exposing the pattern to light
removing the exposed portions to form spaces;
coating a black matrix layer to a predetermined thickness on the transparent substrate on which the spaces are formed; and
developing the black matrix layer.
